(19) United States
(12) Patent Application Publication
(10) Pub. No.: US 2010/0065844 A1
(43) Pub. Date: Mar. 18, 2010

(54) THIN FILM TRANSISTOR AND METHOD OF MANUFACTURING THIN FILM TRANSISTOR

(75) Inventor: Kazuhiko Tokunaga, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/557,212

(22) Filed: Sep. 10, 2009

(30) Foreign Application Priority Data
Sep. 18, 2008 (JP) 2008-239783

(51) Int. Cl. H01L 29/786; H01L 21/30

(52) U.S. Cl. 257/43; 438/104; 257/E29.296; 257/E21.211

(57) ABSTRACT

The present invention provides a thin film transistor including: a channel layer mainly containing a conductive oxide semiconductor; a pair of electrodes on the channel layer; and a protective film covering an exposed surface of the channel layer, exposed to the gap between the pair of electrodes. The protective film includes at least an oxygen transmission film in contact with the channel layer, and an oxygen disturbance film hardly transmitting oxygen in comparison with the oxygen transmission film, in this order from the channel layer side. A length of the oxygen disturbance film in a direction where the pair of electrodes face each other is equal to or larger than a value obtained by multiplying a width of the pair of electrodes in a direction orthogonal to the direction where the pair of electrodes face each other by 0.55.

### BACKGROUND OF THE INVENTION

1. Field of the Invention

The present invention relates to a thin film transistor (TFT) using a conductive semiconductor oxide as a channel, and a method of manufacturing the thin film transistor.

2. Description of the Related Art

In recent years, a thin film transistor using a conductive oxide semiconductor as a channel has been used as a drive transistor in an organic EL panel. There is a possibility that the thin film transistor will be used as a drive transistor in a liquid crystal panel in the future, and thus the thin film transistor attracts attention.

However, it is known that the thin film transistor is sensitive to atmosphere, and the characteristics of the thin film transistor change depending on the atmosphere during operation and storage. As a reason for that, it is said that material mainly containing ZnO (refer to Japanese Unexamined Patent Publication No. 2002-76356) and material mainly containing In-M-Zn—O (M is one or more of Ga, Al, and Fe), which are each typically used as an oxide semiconductor in the thin film transistor, are easily absorbed and desorbed with water, other gas molecules, and the like in the atmosphere. Thus, for example, Japanese Unexamined Patent Publication No. 2007-73705 proposes that a channel layer is covered with a protective film.

### SUMMARY OF THE INVENTION

In the above-described thin film transistor, there is a case where deterioration of TFT characteristics occurs due to oxygen loss. In the case where such deterioration occurs, it is necessary to perform heat processing in air or in atmosphere to which oxygen is introduced.

However, in the case where the channel layer is covered with the protective film as described in Japanese Unexamined Patent Publication No. 2007-73705, even when the above-described heat processing is performed, there are issues as follows. When the protective film is made of a film which does not allow oxygen passing through it (for example, a film containing SiN, metal, or the like), there is an issue that oxygen is not diffused to the channel layer, and TFT characteristics are not recovered. When the protective film is made of a film which allows oxygen passing through it (for example, a film containing SiO₂), since oxygen is diffused to the channel layer, it is possible to recover TFT characteristics. However, the protective film does not serve as a protective film, and this leads to an issue that TFT characteristics change by being influenced from atmosphere during operation.

In this manner, in the related art, there is no protective film capable of realizing both protection of the channel layer and recovery of TFT characteristics.

In view of the foregoing, it is desirable to provide a thin film transistor including a protective film capable of realizing both protection of a channel layer and recovery of TFT characteristics at the same time, and a method of manufacturing the thin film transistor.

According to an embodiment of the present invention, there is provided a thin film transistor including: a channel layer mainly containing a conductive oxide semiconductor; a pair of electrodes on the channel layer, facing each other with a predetermined gap in between in an in-plane direction of the channel layer; and a protective film covering an exposed surface of the channel layer, exposed to the gap between the pair of electrodes. The protective film includes at least an oxygen transmission film in contact with the channel layer, and an oxygen disturbance film hardly transmitting oxygen in comparison with the oxygen transmission film, in this order from the channel layer side. Here, a length of the oxygen disturbance film in a direction where the pair of electrodes face each other is equal to or larger than a value obtained by multiplying a width of the pair of electrodes in a direction orthogonal to the direction where the pair of electrodes face each other by 0.55.

According to an embodiment of the present invention, there is provided a method of manufacturing a thin film transistor including steps (A) to (C) below:
(A) forming a protective film on a channel layer mainly containing a conductive oxide semiconductor, the protective film covering a part of the channel layer, and including at least an oxygen transmission film in contact with the channel layer, and an oxygen disturbance film hardly transmitting oxygen in comparison with the oxygen transmission film, in this order from the channel layer side;
(B) forming a pair of electrodes facing each other with the protective film in between so that a length of the oxygen disturbance film in a direction where the pair of electrodes face each other is equal to or larger than a value obtained by multiplying a width of the pair of electrodes in a direction orthogonal to the direction where the pair of electrodes face each other by 0.55; and
(C) exposing the protective film to atmosphere containing oxygen, at high temperature and with time within a range that the channel layer is unchanged in composition.

In the thin film transistor and the method of manufacturing the thin film transistor according to the embodiment of the present invention, in the channel layer, a portion (exposed surface) to be a channel region is covered with the protective film including the oxygen transmission film in contact with the channel layer, and the oxygen disturbance film hardly transmitting oxygen in comparison with the oxygen transmission film, in this order from the channel layer side. Moreover, a length of the oxygen disturbance film in a direction where the pair of electrodes face each other is equal to or larger than a value obtained by multiplying a width of the pair of electrodes in a direction orthogonal to the direction where the pair of electrodes face each other by 0.55. Therefore, by performing the heat processing in atmosphere containing oxygen under the predetermined conditions, the oxygen is diffused to the channel region through the oxygen transmission film, and it is possible to avoid oxygen loss in the channel region. Moreover, during operation, since the oxygen disturbance film serves as disturbance, it is possible to suppress that the oxygen in the channel region is diffused to the outside, and that the oxygen loss occurs in the channel region.

According to the thin film transistor and the method of manufacturing the thin film transistor according to the embodiment of the present invention, in the channel layer, a portion (exposed surface) to be a channel region is covered with the protective film including the oxygen transmission film in contact with the channel layer, and the oxygen disturbance film hardly transmitting oxygen in comparison with the oxygen transmission film, in this order from the channel layer side. Moreover, a length of the oxygen disturbance film in a direction where the pair of electrodes face each other is equal to or larger than a value obtained by multiplying a width of the pair of electrodes in a direction orthogonal to the direction where the pair of electrodes face each other by 0.55. Therefore, it is possible to recover TFT characteristics during manufacture, and it is possible to protect the channel layer during operation. In this manner, it is possible to realize both protection of the channel layer and recovery of TFT characteristics at the same time in the present invention.

Other and further objects, features and advantages of the invention will appear more fully from the following description.

### BRIEF DESCRIPTION OF THE DRAWINGS

FIGS. 1A to 1C are a top view and cross-sectional views, respectively, of a thin film transistor according to an embodiment of the present invention.

FIGS. 2A and 2B are schematic views schematically illustrating a step in manufacture process of the thin film transistor of FIG. 1.

FIG. 3 is a view illustrating determination results of current-voltage characteristics according to a thin film transistor of examples and comparative examples.

FIG. 4 is a current-voltage characteristics view of a thin film transistor according to a first example.

FIG. 5 is a current-voltage characteristics view of a thin film transistor according to a second example.

FIG. 6 is a current-voltage characteristics view of a thin film transistor according to a third example.

FIG. 7 is a current-voltage characteristics view of a thin film transistor according to a fourth example.

FIG. 8 is a characteristic view illustrating current-voltage characteristics of a thin film transistor according to a first comparative example.

FIG. 9 is a current-voltage characteristic view of a thin film transistor according to a second comparative example.

FIG. 10 is a current-voltage characteristic view of a thin film transistor according to a third comparative example.

FIG. 11 is a current-voltage characteristic view of a thin film transistor according to a fourth comparative example.

### DETAILED DESCRIPTION OF THE PREFERRED EMBODIMENTS

Preferred embodiments of the present invention will be described in detail with reference to the accompanying drawings.

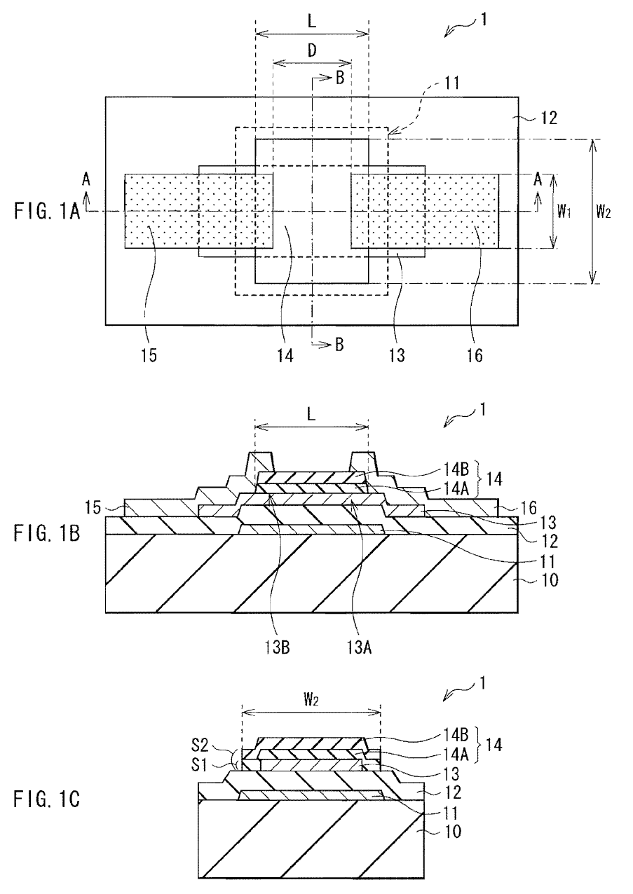

FIG. 1A illustrates the top configuration of a thin film transistor 1 according to an embodiment of the present invention. FIG. 1B illustrates the cross-sectional configuration of the thin film transistor 1, as viewed from direction of A-A in FIG. 1A. FIG. 1C illustrates the cross-sectional configuration of the thin film transistor 1, as viewed from direction of B-B in FIG. 1A. Although not illustrated in the figure, the thin film transistor 1 according to the embodiment is, for example, a TFT formed together with an organic EL element and a liquid crystal element, on an insulating substrate such as a plastic film substrate and a glass substrate, and suitably used as a switching element performing switching drive of the organic EL element and the liquid crystal element.

This thin film transistor 1 is a bottom-gate type transistor including a gate electrode 11, a gate insulating film 12, a channel layer 13, a drain electrode 15, and a source electrode 16 in this order from a substrate 10 side on the substrate 10.

The substrate 10 is, for example, an insulating substrate such as a plastic film substrate and a glass substrate. The gate electrode 11 is made of, for example, Mo. The gate electrode 11 is formed in a region including a region where the gate electrode 11 and a channel region 13A which will be described later face each other, and has, for example, a rectangle shape. Thereby, the gate electrode 11 is a low-resistance electrode, and serves as a light shielding film which blocks light from the substrate 10 side from entering to the channel region 13A.

The gate insulating film 12 mainly contains, for example, silicon oxide (SiO₂), silicon nitride (SiN), yttrium oxide (Y₂O₃), aluminum oxide (Al₂O₃), hafnium oxide (Hf₂O₂), titanium oxide (TiO₂), or the like. The gate insulating film 12 is formed so as to cover the gate electrode 11, and is formed, for example, over the whole surface of the substrate 10 including the gate electrode 11.

The channel layer 13 mainly contains, for example, a conductive oxide semiconductor such as zinc oxide (ZnO), indium tin oxide (ITO), and In-M-Zn—O (M is one or more of Ga, Al, Fe, and Sn). It is preferable that the electron carrier concentration of the channel layer 13 is less than 10¹⁸/cm⁻³ and the mobility of the channel layer 13 is approximately slightly over 1 cm²/(V second). The channel layer 13 is formed so as to intersect a region where the channel layer 13 and the gate electrode 11 face each other, and is formed so as to extend in the direction (will be described later) where the drain electrode 15 and the source electrode 16 face each other. In the upper surface of the channel layer 13, a gap between the drain electrode 15 and the source electrode 16 is an exposed surface 13B which is not covered with the drain electrode 15 and the source electrode 16. In the channel layer 13, a predetermined region including the exposed surface 13B is a channel region 13A.

The drain electrode 15 and the source electrode 16 are made of, for example, Mo. The drain electrode 15 and the source electrode 16 face each other with a predetermined gap in between, in the in-plane direction of the channel layer 13. A space D of the gap is equal to or smaller than a channel length which will be described later. A width W1 of the drain electrode 15 and the source electrode 16 is also equal to or smaller than the channel length.

In the embodiment, the term “width” (for example, the above-described width W1) indicates the length in the direction orthogonal to the facing direction of the drain electrode 15 and the source electrode 16, and the term “length” (for example, a length L which will be described later) indicates the length in the facing direction of the drain electrode 15 and the source electrode 16.

Moreover, the thin film transistor 1 includes a protective film 14 on the exposed surface 13B in the channel layer 13. The protective film 14 is formed in contact with the exposed surface 13B, and covers the exposed surface 13B. The protective film 14 is formed so as to intersect the facing region of the protective film 14 and the exposed surface 13B, and is formed so as to extend in the width direction of the drain electrode 15 and the source electrode 16. Moreover, in the protective film 14, both side faces (both end faces) in the facing direction of the drain electrode 15 and the source electrode 16 are in contact with the drain electrode 15 and the source electrode 16, and are covered with the drain electrode 15 and the source electrode 16.

Here, the length L of the protective film 14 is equal to the channel length of the thin film transistor 1, and is equal to or larger than a value obtained by multiplying the width W1 of the drain electrode 15 and the source electrode 16 by 0.55. Moreover, the length L of the protective film 14 is larger than the space D of the gap between the drain electrode 15 and the source electrode 16. The width W2 of the protective film 14 is larger than the width W1 of the drain electrode 15 and the source electrode 16, and is such a width that at least both side faces (both side faces in the width direction) of the channel layer 13 are covered with the protective film 14. Thus, in the protective film 14, both side faces (both end faces) in the width direction of the drain electrode 15 and the source electrode 16 are not covered with the drain electrode 15 and the source electrode 16, and are exposed to the outside.

The protective film 14 includes at least an oxygen transmission film 14A in contact with the exposed surface 13B in the channel layer 13, and an oxygen disturbance film 14B hardly transmitting oxygen, in comparison with the oxygen transmission film 14A, and has the stacked structure. Both of the oxygen transmission film 14A and the oxygen disturbance film 14B are formed over the whole in-plane direction of the protective film 14. With end faces of the oxygen transmission film 14A and the oxygen disturbance film 14B, a side face (end face) S2 of the protective film 14 is formed. The end face S2 is a flat inclined face, or a flat vertical face. To the end face S2, a side face (end face) S1 of the oxygen transmission film 14A is exposed.

The oxygen transmission film 14A mainly contains, for example, silicon nitride (SiN) or metal oxide (for example, Al₂O₃). On the other hand, the oxygen disturbance film 14B mainly contains, for example, silicon oxide (SiO₂). The oxygen transmission film 14A and the oxide disturbance film 14B are, for example, each 100 nm or more and 300 nm or less in thickness, and preferably approximately 200 nm in thickness.

Next, an example of a method of manufacturing the thin film transistor 1 according to the embodiment will be described.

First, after forming the gate electrode 11 on the substrate 10, the gate insulating film 12 is formed. Next, after forming the channel layer 13, the protective film 14 is formed by stacking at least the oxygen transmission film 14A and the oxygen disturbance film 14B in this order on the channel layer 13. At this time, the protective film 14 is formed so as to intersect a part of the channel layer 13 from the width direction. Then, after depositing material used for the drain electrode 15 and the source electrode 16 over the whole surface of the protective film 14, the material is patterned and etched. Thereby, a pair of the drain electrode 15 and the source electrode 16 (hereafter, referred to as the drain electrode 15 and the like) facing each other with the protective film 14 in between are formed. At this time, the drain electrode 15 and the like are formed so that the length of the oxygen disturbance film 14B, in the facing direction of the drain electrode 15 and the like, is equal to or larger than a value obtained by multiplying the width W1 of the drain electrode 15 and the like, in the direction orthogonal to the facing direction of the drain electrode 15 and the like, by 0.55 (0.55×W1).

In the above-described step, oxygen in the channel layer 13 (especially the portion exposed to the outside) is mostly lost, and resistance of the channel layer 13 is reduced. When this situation is left as it is, favorable TFT characteristics are not obtained. Thus, to avoid the oxygen loss, the heat processing is performed while exposing the protective film 14 to atmosphere containing oxygen, the heat processing performed at high temperature and with time, within a range that the channel layer 13 does not change in composition. In this manner, the thin film transistor 1 according to the embodiment is manufactured.

Next, effects of the thin film transistor 1 according to the embodiment will be described.

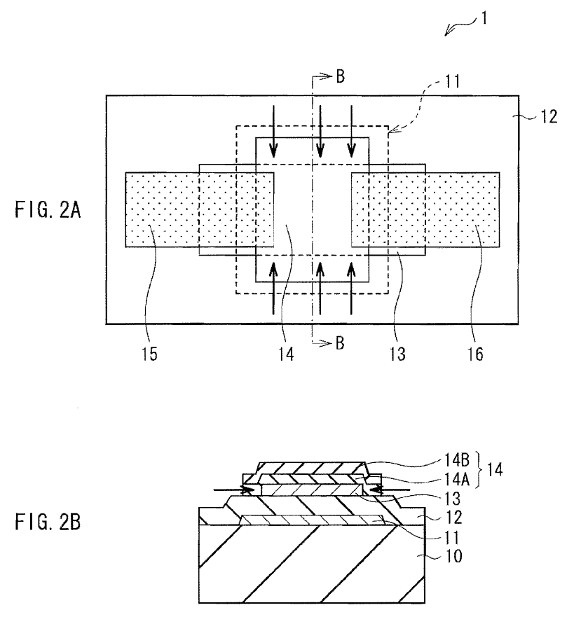

In the embodiment, in the channel layer 13, the portion (exposed surface 13B) to be the channel region 13A is covered with the protective film 14 including the oxygen transmission film 14A in contact with the channel layer 13, and the oxygen disturbance film 14B in this order from the channel layer 13 side. Here, the length L of the protective film 14 is equal to or larger than a value obtained by multiplying the width W1 of the drain electrode 15 and the source electrode 16 by 0.55 (0.55×W1). Thereby, in the manufacture process, in the case where the heat processing in the atmosphere with a predetermined oxygen concentration is performed at high temperature and with time, within a range that the channel layer 13 does not change in composition, for example, as indicated with arrows in FIGS. 2A and 2B, oxygen is diffused to the channel region 13A through the oxygen transmission film 14A, and it is possible to avoid the oxygen loss in the channel region 13A. Thereby, resistance of the channel region 13A increases, and it is possible to recover TFT characteristics.

Here, for example, the expression “atmosphere with a predetermined oxygen concentration” indicates nitrogen-oxygen atmosphere within a range from 0.1% to 50%, and preferably indicates nitrogen-oxygen atmosphere within a range from 10% to 40%. For example, the expression “high temperature within a range that the channel layer 13 does not change in composition” indicates temperature within a range from 100° C. to 500° C., and preferably indicates temperature within a range from 200° C. to 350° C. The expression “time within a range that the channel layer 13 does not change in composition” indicates, for example, approximately 2 hours.

With an increase of the heat processing time, the diffusion distance of oxygen increases. Therefore, in the case where the heat processing time is set remarkably long with temperature slightly reduced from that described above, even when the length L is smaller than a value obtained by multiplying the width W1 by 0.55 (0.55×W1), it is possible to avoid the oxygen loss in the channel region 13A. However, in the case of considering mass-production, it is difficult to excessively increase the heat processing time. Accordingly, there are conditions for the length L and the width W1 so that it is possible to avoid the oxygen loss in the channel region 13A under certain conditions allowing the mass-production (for example, conditions described above). It is possible to say that the conditions for the length L and the width W1 are as follows.

L≧0.55×W1

In the case where the conditions for the length L and the width W1 are as described above (L≧0.55×W1), during operation, since the oxygen disturbance film 14B serves as disturbance, it is suppressed that oxygen in the channel region 13A is diffused to the outside and thereby that the oxygen loss occurs in the channel region 13A. Here, an outlet where oxygen flows outside from the oxygen transmission film 14A due to the diffusion, and an inlet where oxygen enters to the oxygen transmission film 14A from the outside are located in the same place. Thus, it seems like oxygen freely flows inside and outside through the place of the inlet and the outlet. However, by limiting the region of the inlet and the outlet to the end face of the oxygen transmission film 14A, and reducing the size of the inlet and the outlet, the outside is oxygen atmosphere, and it is possible for oxygen to easily flow inside from the small inlet when being heated, while it is difficult for oxygen to flow outside from the oxygen transmission film 14A due to the diffusion during operation. Therefore, it is possible to maintain resistance of the channel region 13A high, and it is possible to protect the channel layer 13 during operation.

In this manner, in the embodiment, TFT characteristics are recovered during manufacture, and the channel layer 13 is protected during operation. Therefore, it is possible to realize both protection of the channel layer 13 and recovery of TFT characteristics.

In the embodiment, design of the thin film transistor 1 is defined. However, by parallel connection of the thin film transistor 1 to a device, it is possible to obtain a large amount of current, and by changing the width W1 of the drain electrode 15 and the source electrode 16, it is possible to easily obtain a small amount of current. Therefore, in the embodiment, there is no limitation caused by the defined design of the thin film transistor 1.

### Examples

Next, examples of the thin film transistor 1 according to the embodiment will be described in comparison with comparative examples. The thin film transistor was manufactured as follows in each of the examples and the comparative examples. First, a gate electrode 11 of Mo was formed on a substrate 10, and then a gate insulating film 12 was formed through the use of P-CVD method. Next, a channel layer 13 of In—Ga—Zn—O was formed, and then an oxygen transmission film 14A of a SiO film with a thickness of 200 nm, and an oxygen disturbance film 14B of a SiN film with a thickness of 200 nm were stacked in this order on the channel layer 13. After that, Mo was deposited on the surface, and a drain electrode 15 and a source electrode 16 were formed by performing patterning and etching. In this manner, the thin film transistor according to each of the examples and the comparative examples was manufactured.

In an example, a width W1 was 5 μm, and a length L was 4 μm, 5 μm, 6 μm, 7 μm, 8 μm, 10 μm, 11 μm, 12 μm, or 20 μm. In another example, a width W1 was 10 μm, and a length L was 4 μm, 5 μm, 6 μm, 7 μm, 8 μm, 10 μm, 11 μm, 12 μm, or 20 μm. In still another example, a width W1 was 20 μm, and a length L was 11 μm, 12 μm, 20 μm, 30 μm, or 50 μm. In a comparative example, a width W1 was 20 μm, and a length L was 8 μm, or 10 μm. In another comparative example, a width W1 was 50 μm, and a length L was 20 μm, 30 μm, 50 μm, or 100 μm.

Next, to avoid oxygen loss in the channel layer 13, the heat processing was performed in oxygen atmosphere. Specifically, in atmosphere containing nitride (N2) and oxygen (O2), the heat processing was performed under the conditions that the oxygen concentration was approximately 40%, the heat processing temperature was 300° C., and the heat processing time was 2 hours.

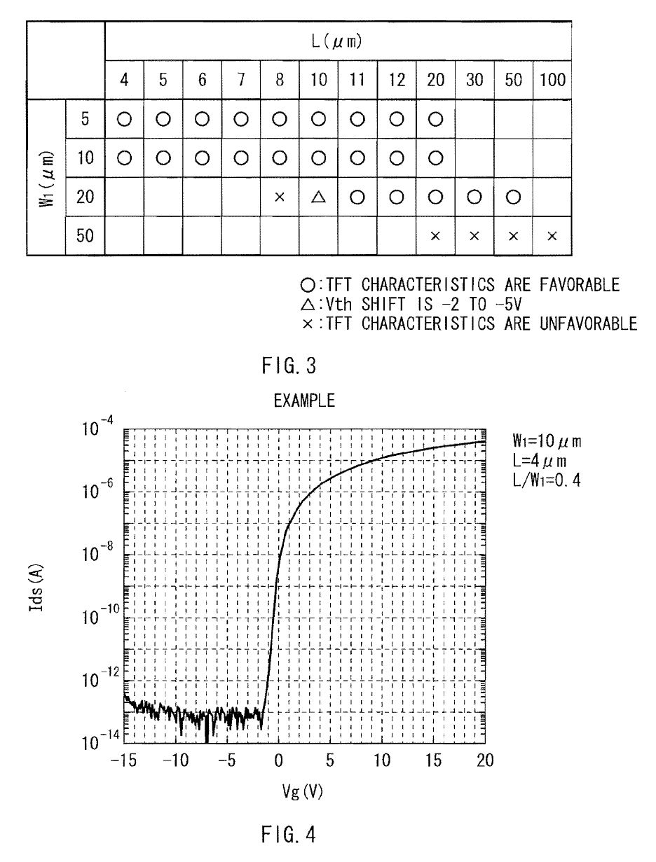

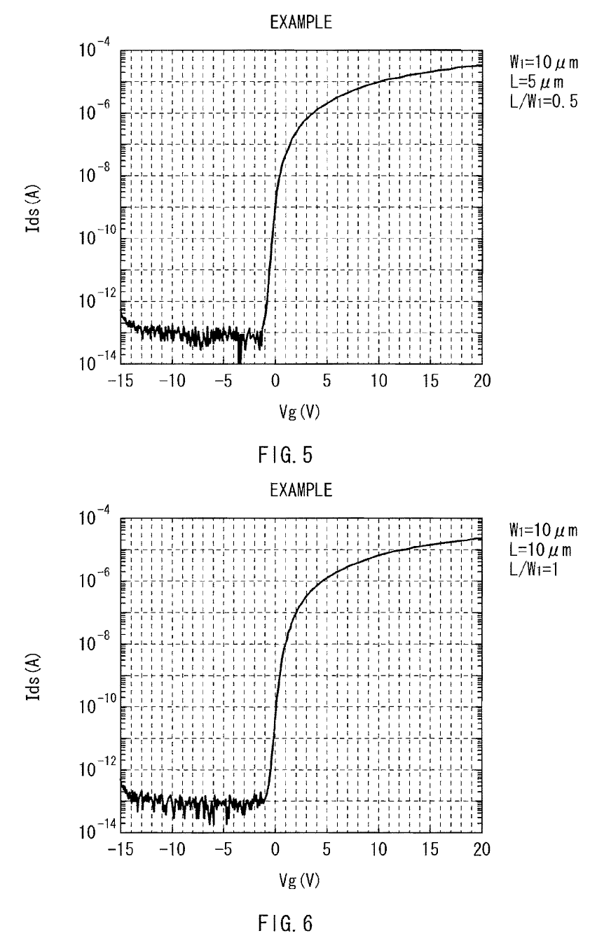

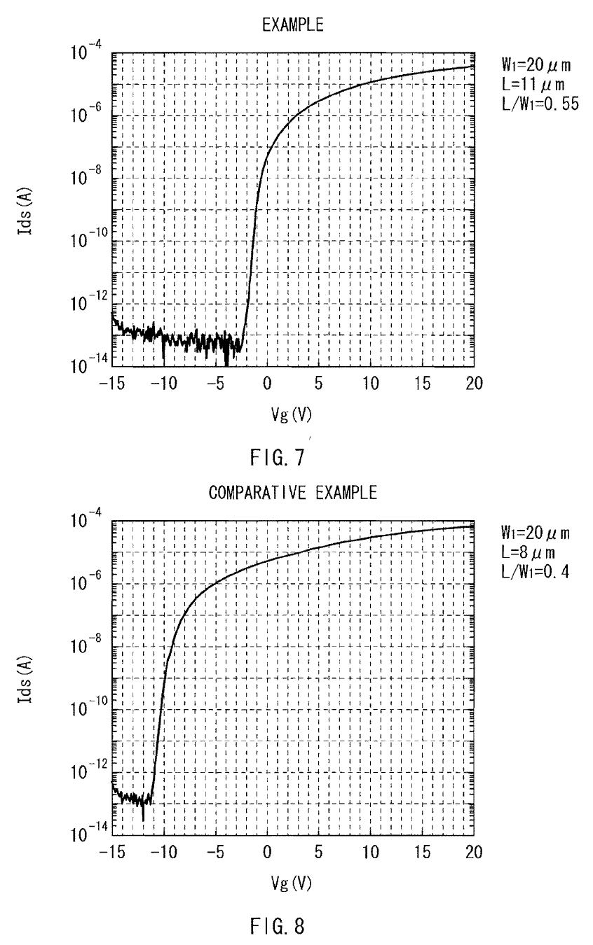

After that, under the conditions that a voltage of 10V was applied between the drain electrode 15 and the source electrode 16, the change in the current (current-voltage characteristics) between the source and the drain was measured while the voltage applied to the gate electrode 11 was changed from −15V to 20V. As a result, in the examples, oxygen reached the channel layer 13 through the oxygen transmission film 14A, and it was possible to avoid the oxygen loss in the channel layer 13. As a result, in the case where the width W1 was 5 μm or 10 μm, as indicated in FIGS. 3 to 6, irrespective of the size of the length L, it was possible to recover TFT characteristics, and favorable TFT characteristics were obtained. Changes of TFT characteristics were not found during operation. Moreover, as indicated in FIGS. 3 and 7, even in the case where the length L was 11 μm, it was possible to recover TFT characteristics, and favorable TFT characteristics were obtained. Changes of TFT characteristics were not found during operation.

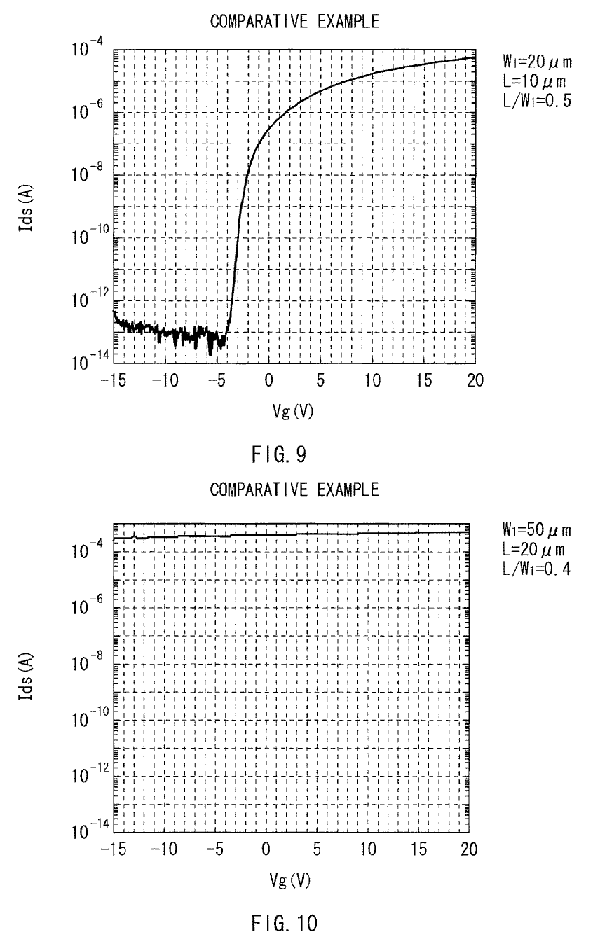

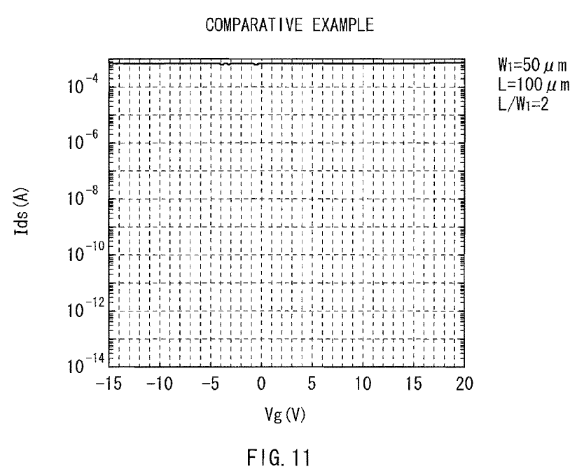

On the other hand, in the comparative examples, oxygen did not sufficiently reach the channel layer 13, and it was difficult to avoid the oxygen loss in the channel layer 13. As a result, as indicated in FIGS. 3, 8, and 9, in the case where the width W1 was 20 μm and the length L was 8 μm or 10 μm, TFT characteristics were not recovered while the threshold voltage (Vth) shift was 2V to 5V above from usual. As indicated in FIGS. 3, 10, and 11, in the case where the width W1 was 50 μm, irrespective of the size of the length L, transistor characteristics were not indicated.

From these, in the case where the width W1 was equal to or smaller than 10 μm, and the case where the width W1 was larger than 10 μm and smaller than 50 μm and the length L was set so that L/W1 was approximately 0.55 or more, it was understood that both protection of the channel layer 13 and recovery of TFT characteristics were realized.

Hereinbefore, although the thin film transistor according to the embodiment of the present invention is described with the embodiment and the examples, the present invention is not limited to the embodiment and the like, and the configuration of the thin film transistor according to the embodiment of the present invention may be freely modified as long as effects similar to those of the embodiment are obtained.

For example, in the embodiment and the like, as indicated in FIG. 1C, in the oxygen transmission film 14A, only the end face S1 is exposed to the end face S2 of the protective film 14. However, for example, not only the end face S1 of the oxygen transmission film 14A, but also the vicinity of the end face in the upper surface of the oxygen transmission film 14A may be exposed to the end face S2 of the protective film 14, although not illustrated in the figure.

In the embodiment and the like, as indicated in FIG. 1A, the width W2 of the oxygen transmission film 14A and the oxygen disturbance film 14B is larger than the width W1 of the drain electrode 15 and the source electrode 16. However, for example, the width W2 may be equal to the width W1 in size, although not illustrated in the figure. In such a case, the both side faces (both side faces in the width direction) of the channel layer 13 are exposed. However, it is possible to obtain effects similar to those of the embodiment, in the case where the oxygen loss occurs only in the outer edge (outer edge in the width direction) of the channel region 13A.

In the embodiment and the like, as indicated in FIGS. 1B and 1C, the case is indicated where the thin film transistor 1 is the bottom-gate type. However, for example, the thin film transistor 1 may be the top-gate type, including a gate insulating film 12 and a gate electrode 11 in this order from an exposed surface 13B side on the exposed surface 13B in a channel layer 13, although not illustrated in the figure.

In the embodiment and the like, as indicated in FIG. 1A, a set of the gate electrode 11, the drain electrode 15, and the source electrode 16 are arranged with respect to the channel layer 13. However, for example, a plurality of sets of these electrodes may be arranged, although not illustrated in the figure.

The present application contains subject matter related to that disclosed in Japanese Priority Patent Application JP 2008-239783 filed in the Japan Patent Office on Sep. 18, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor comprising:
a channel layer mainly containing a conductive oxide semiconductor;
a pair of electrodes on the channel layer, facing each other with a predetermined gap in between in an in-plane direction of the channel layer; and
a protective film covering an exposed surface of the channel layer, exposed to the gap between the pair of electrodes, wherein
the protective film includes at least an oxygen transmission film in contact with the channel layer, and an oxygen disturbance film hardly transmitting oxygen in comparison with the oxygen transmission film, in this order from the channel layer side, and
a length of the oxygen disturbance film in a facing direction of the pair of electrodes is equal to or larger than a value obtained by multiplying a width of the pair of electrodes in a direction orthogonal to the direction where the pair of electrodes face each other by 0.55.

2. The thin film transistor according to clam 1, wherein a width of the oxygen transmission film and the oxygen disturbance film in the direction orthogonal to the direction where the pair of electrodes face each other is larger than the width of the pair of electrodes in the direction orthogonal to the direction where the pair of electrodes face each other.

3. The thin film transistor according to claim 1, wherein, in the oxygen transmission film, only an end face is exposed to an end face of the protective film.

4. The thin film transistor according to claim 1, wherein the oxygen disturbance film mainly contains SiN.

5. The thin film transistor according to claim 1, wherein the oxygen transmission film mainly contains SiO₂.

6. The thin film transistor according to claim 1, wherein a gate insulating film and a gate electrode are provided in this order from the exposed surface side of the channel layer, below the exposed surface of the channel layer.

7. A method of manufacturing a thin film transistor comprising the steps of:
forming a protective film on a channel layer mainly containing a conductive oxide semiconductor, the protective film covering a part of the channel layer, and including at least an oxygen transmission film in contact with the channel layer, and an oxygen disturbance film hardly transmitting oxygen in comparison with the oxygen transmission film, in this order from the channel layer side;
forming a pair of electrodes facing each other with the protective film in between so that a length of the oxygen disturbance film in a direction where the pair of electrodes face each other is equal to or larger than a value obtained by multiplying a width of the pair of electrodes in a direction orthogonal to the direction where the pair of electrodes face each other by 0.55; and
exposing the protective film to atmosphere containing oxygen, at high temperature and with time within a range that the channel layer is unchanged in composition.
